(19) United States
(12) Patent Application Publication
(10) Pub. No.: US 2015/0243700 A1
(43) Pub. Date: Aug. 27, 2015

(54) SEMICONDUCTOR DEVICE

(71) Applicant: KABUSHIKI KAISHA TOSHIBA, Tokyo (JP)

(72) Inventor: Tetsu MOROOKA, Yokohama-shi, Kanagawa (JP)

(21) Appl. No.: 14/298,622

(22) Filed: Jun. 6, 2014

(30) Foreign Application Priority Data
Feb. 27, 2014 (JP) 2014-037372

(51) Int. Cl. H01L 27/146

(52) U.S. Cl. CPC H01L 27/14643; H01L 27/14612; H01L 27/14689; H01L 27/1461; H01L 27/1463

(57) ABSTRACT

According to one embodiment, a semiconductor device includes a photodiode. The photodiode is embedded in a pixel region, and has a P-type region formed along a first trench at a side of a second surface. An impurity concentration of the P-type impurities along the first trench is different between at the side of the second surface and at a side of a first surface, and an impurity concentration of the P-type region is higher at the side of the second surface than at the side of the first surface.

### CROSS-REFERENCE TO RELATED APPLICATIONS

This application is based upon and claims the benefit of priority from Japanese Patent Application No. 2014-037372, filed on Feb. 27, 2014; the entire contents of all of which are incorporated herein by reference.

### FIELD

Embodiments described herein relate to a semiconductor device.

### BACKGROUND

With the advance of semiconductor device manufacturing technology, a CMOS image sensor technique is widely used, which takes images by transferring electrons from a photodiode to a floating diffusion via a transfer gate.

In a CMOS image sensor, pixels has been scaled down for reducing chip size and increasing resolution. However, recent scaling down of the pixels disadvantageously results in mixed color between the pixels adjacent to one another, decrease of the number of electrons in saturation-state due to decrease in photodiode area, and increase in noise due to reduce in size of pixel transistors.

In order to solve these problems, some techniques are proposed such as a front side deep trench isolation (FDTI) technique that completely separates pixels by deep trenches between the pixels, and a three dimension pixel technique that embeds photodiode into a Si substrate, and removes the photodiode from a Si substrate surface to avoid shrinking photodiode and pixel transistor.

A proposed pixel structure is achieved by combining the FDTI technique and the three dimension pixel technique. In the case of such a pixel structure, though a P-type region of the photodiode is formed on the side face of the FDTI, the P-type region is also formed on the upper portion of the FDTI, which is not configured as photodiode. This P-type region has a high impurity concentration, which may disadvantageously cause junction leakage current from pixel transistors.

The N-type region of the photodiode is formed in a Si substrate. By increasing impurity concentration in the N-type region to increase the capacity, complete depletion of the N-type region is not achieved at the time of carrier accumulation, which results in undesirably high electric potential. It prevents carrier transfer when a transfer is needed. Because of this problem, impurity concentration of the N-type region is restricted, and the number of saturation electrons cannot be increased proportional to the size of the photodiode.

### BRIEF DESCRIPTION OF THE DRAWINGS

FIGS. 1A and 1B are cross-sectional views schematically illustrating a configuration of an image sensor according to a first embodiment, and FIG. 1B is a view illustrating a cross section taken along the line A-A in FIG. 1A;

FIGS. 2A through 2H are views illustrating fabrication processes of the image sensor according to the first embodiment;

FIGS. 3A and 3B are cross-sectional views schematically illustrating a configuration of an image sensor according to a second embodiment, and FIG. 3B is a view illustrating a cross section taken along the line A-A in FIG. 3A;

FIGS. 4A through 4H are views illustrating fabrication processes of the image sensor according to the second embodiment;

FIGS. 5A and 5B are cross-sectional views schematically illustrating a configuration of an image sensor according to a third embodiment, and FIG. 5B is a view illustrating a cross section taken along the line A-A in FIG. 5A; and

FIGS. 6A through 6H are views illustrating fabrication processes of the image sensor according to the third embodiment.

### DETAILED DESCRIPTION

According to one embodiment of the present invention, a semiconductor device includes a pixel region formed on a semiconductor substrate. The pixel region is separated by a first trench passing from a first surface to a second surface. The photodiode is embedded in the pixel region, and has a P-type region formed along the first trench at a side of the second surface. A MISFET is formed on the first surface of the semiconductor substrate and has a transfer gate transferring an electric charge from the photodiode. An impurity concentration of the P-type impurities along the first trench is different between at a side of the first surface and at the side of the second surface, and an impurity concentration of the P-type region formed at the side of the second surface and constituting the photodiode is higher than an impurity concentration at the side of the first surface.

Exemplary embodiments of an image sensor as a semiconductor device and a method for fabricating the image sensor will be explained below in detail with reference to the accompanying drawings. The present invention is not limited to the following embodiments.

### First Embodiment

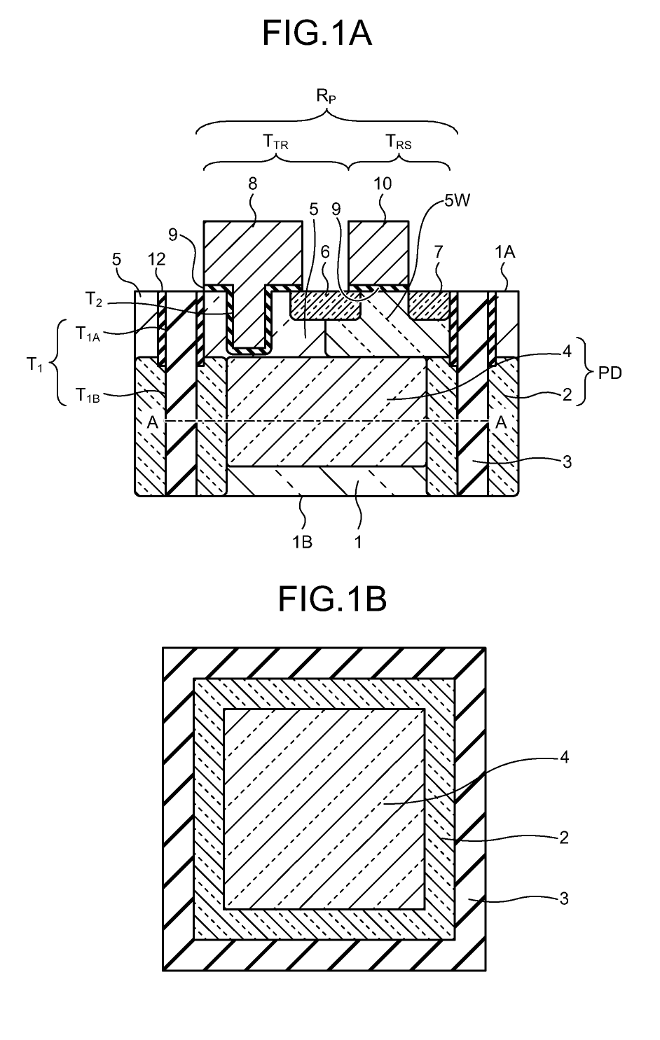

FIGS. 1A and 1B are cross-sectional views schematically illustrating a configuration of the image sensor according to the first embodiment. FIG. 1B is a view illustrating a cross section taken along the line A-A in FIG. 1A. The first embodiment provides a semiconductor device including a CMOS image sensor. The image sensor having a CMOS structure is formed in a pixel region R_{P} that is separated by the first trenches T₁. The image sensor includes a photoelectric conversion portion and a transferring portion. The photoelectric conversion portion includes a photodiode PD that converts an incident light into a signal charge photo-electrically, and the transferring portion transfers the signal charge generated at the photoelectric conversion portion from the photodiode PD to a floating diffusion portion 6. The transferring portion includes a transfer transistor T_{TR} and a reset transistor T_{RS}, and the reset transistor T_{RS} resets an electric charge transferred to the floating diffusion portion 6. A P-type single-crystal silicon substrate is used as a substrate 1, and in the drawing, the first surface 1A is at an upside, and the second surface 1B is at a downside, which is a photo-receiving surface. In addition, as illustrated in FIG. 1B, in the pixel region R_{P} separated by the first trenches T₁, a P-type region 2 is formed along all inner sidewalls of the first trenches T₁ at a side of the second surface 1B. A vertical PN-junction between the P-type region 2 and the N-type region 4 is formed inside the P-type region 2. This forms the photodiode PD.

The photodiode PD is embedded in the pixel region R_{P}, and has the P-type region 2 formed along the first trench T₁, and the N-type region 4, as a charge storage region formed inside the P-type region 2. The transferring portion includes the transfer transistor T_{TR} for transferring an electric charge from the photodiode PD. The transfer transistor T_{TR} is a trench type MISFET including a transfer gate 8 formed in a second trench T₂ that is formed from the first surface 1A of the substrate 1 toward the second surface 1B of the substrate 1, on which the photodiode PD is formed. The P-type region 2 forming a PN-junction is not formed equally between the side of the first surface 1A and the side of the second surface 1B, but is selectively formed at the side of the second surface 1B such that an impurity concentration of the P-type region 2 at the side of the second surface 1B is higher than the impurity concentration of the low concentration N-type region 5 that constitutes the channel region disposed at the side of the first surface 1A.

The first trench T₁ for isolating and defining the pixel region R_{P} is evenly filled with an isolating insulation film 3 from the side of the first surface 1A to the side of the second surface 1B, as well as sidewalls of the trench T_{1A} at the side of the first surface 1A are covered with sidewall insulation films 12 made of, for example, a silicon nitride film. The P-type region is not formed at the region along the sidewall insulation films 12. The region along the sidewall of a trench T_{1B} at the side of the second surface 1B is the P-type region 2 whose P-type impurity concentration is higher than that of the region along the sidewall insulation film 12 formed along the sidewall of the trench T_{1A} at the side of the first surface 1A.

That is, the first trench T₁ can reduce junction leakage current from the transfer transistor T_{TR} and the reset transistor T_{RS} since P-type region having high impurity concentration is not formed along the sidewalls of the trench T_{1A} at the side of the first surface 1A. Because there is no need to consider reduction of the junction leakage current, an impurity concentration of the P-type region 2 can be set to a concentration appropriate for the photodiode PD.

The transfer transistor T_{TR} transfers electric charge stored in the P-type region 2 of the photodiode PD to the floating diffusion portion 6 (n-type region) with an electric potential applied to the transfer gate 8 made of a polycrystalline silicon layer filled into the shallow second trench T₂ formed at the side of the first surface 1A via a silicon oxide film as a gate insulating film 9.

The reset transistor T_{RS} includes, as a channel region, a P-type well 5W formed in the low concentration N-type region 5 at the side of the first surface 1A, and the floating diffusion portion 6 as a source, and controls an electric charge flowing to a drain 7 with an electric potential applied to a reset gate 10 formed on the first surface 1A via the gate insulating film 9.

Here, a P-type single-crystal silicon substrate having an impurity concentration around 10¹⁶ cm⁻³ is used as the substrate 1. The N-type region 4 that constitutes the photodiode PD is an impurity diffused region having an impurity concentration around 10¹⁶ cm⁻³ through 10¹⁷ cm⁻³, which is formed by an ion implantation technique. The P-type region 2 which is formed by a diffusion from the sidewall of the trench and performs a junction with the N-type region 4 is an impurity diffused region having an impurity concentration around 10¹⁸ cm⁻³. In addition, the low concentration N-type region 5, which is a channel of the transfer transistor T_{TR}, has an impurity concentration around 10¹⁶ cm⁻³. This low concentration N-type region 5 may be a low concentration P-type region. Also, the P-type well 5W, which is a channel of the reset transistor T_{RS}, has an impurity concentration around 10¹⁷ cm⁻³.

According to the image sensor of this embodiment, the sidewall insulation film 12 is formed at the upper portion of the first trench T₁ which constitutes the FDTI, that is, at the side of the first surface 1A, and the P-type region is not formed along the sidewall of the first trench T₁, and the P-type region 2 of the photodiode PD is formed only at the side of the second surface 1B. Then the PN-junction is formed approximately parallel to the sidewall of the first trench T₁ and approximately vertical to the first surface 1A and the second surface 1B. Accordingly, a junction leakage current from the transfer transistor T_{TR} and the reset transistor T_{RS} can be reduced since a P-type region having high impurity concentration is not formed at the upper portion of the first trench T₁, that is, at the side of the first surface 1A. Because there is no need to restrict impurity concentration to the level which suppress junction leakage current, impurity concentration of the P-type region 2 of the photodiode PD can be increased so as to increase the capacity of the photodiode PD.

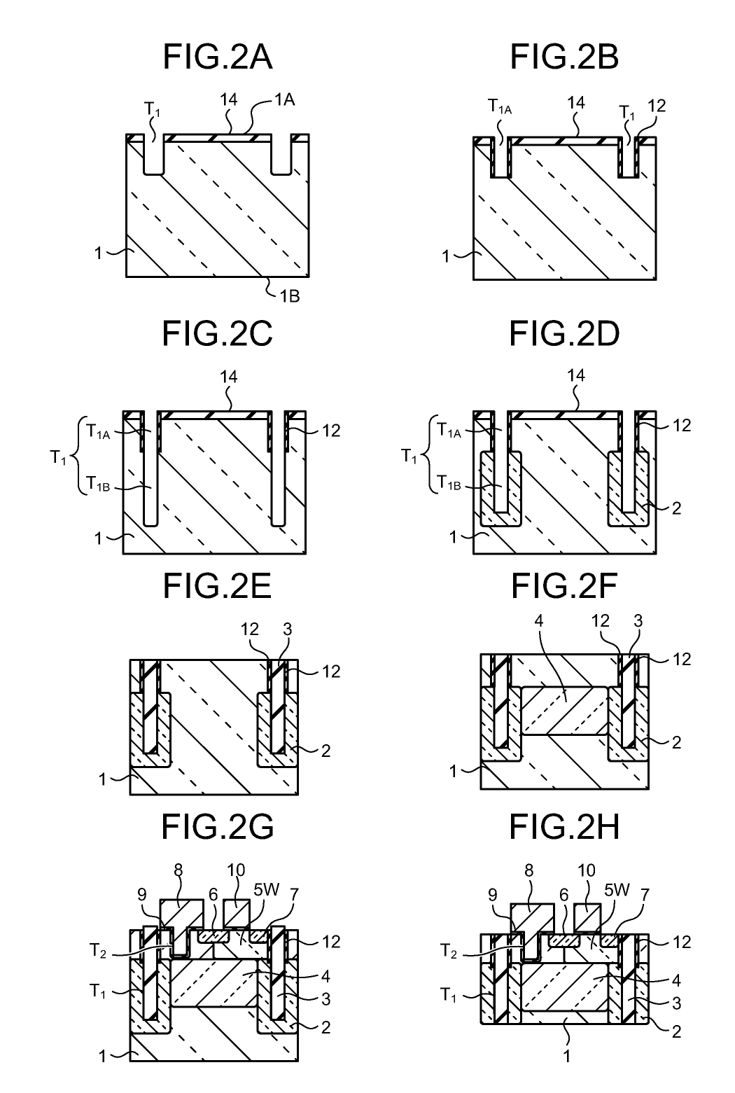

FIGS. 2A through 2H illustrate exemplary fabrication processes of the image sensor according to the first embodiment. First, as illustrated in FIG. 2A, the trench T_{1A} is formed at the side of the first surface 1A by etching part of the first trench T₁ on the substrate 1 by using a hard mask 14 made of a silicon nitride film or similar mask.

Then, as illustrated in FIG. 2B, the sidewall insulation film 12 is formed by forming a silicon nitride film by a Chemical Vapor Deposition (CVD) technique and by etching the silicon nitride film on the plane by anisotropic etching so as to leave the silicon nitride film on the sidewall.

Further, as illustrated in FIG. 2C, the trench T_{1B} is formed at the side of the second surface 1B by etching the substrate 1 until a desired depth such that the trench T_{1B} is coupled to the trench T_{1A} at the side of the first surface 1A.

After that, as illustrated in FIG. 2D, the P-type region 2 is formed by introducing P-type impurities from the side surface by using an ion implantation technique, a solid phase diffusion technique, a plasma doping technique or similar technique. At this time, the trench T_{1A} of the first trench T₁ at the side of the first surface 1A is covered with the sidewall insulation film 12, accordingly impurities are not introduced to the trench T_{1A}.

After that, as illustrated in FIG. 2E, a SiO₂ as the isolating insulation film 3 is filled into the first trench T₁ and the hard mask 14 is peeled off.

Then, as illustrated in FIG. 2F, the N-type region 4 is formed by implanting N-type impurities to a desired depth by the ion implantation technique. Here, the N-type impurities are implanted to a depth where the edge [or: edge face, end face] of sidewall insulation film 12 of the upper portion of the first trench T₁ approximately corresponds to the top surface of the N-type region 4 (the edge at the side of the first surface 1A).

After that, as illustrated in FIG. 2G, the P-type well 5W is formed by implanting P-type impurities into the surface of the first surface 1A. Also, the transfer gate 8 is formed by forming the second trench T₂ and filling the polycrystalline silicon layer into the second trench T₂ via the gate insulating film 9. Here, the gate insulating film 9 is formed by oxidizing the inner wall of the second trench T₂ by a thermal oxidation technique or similar technique. Then the polycrystalline silicon layer is formed on the gate insulating film 9 by the CVD technique or similar technique. Also at the same time, the reset gate 10 is formed on the first surface 1A of the substrate 1 by patterning the polycrystalline silicon layer or similar layer via the gate insulating film 9. Then, using this reset gate 10 as a mask, transfer transistor T_{TR} and the reset transistor T_{RS} are formed by forming the floating diffusion portion 6 and the drain 7 by the ion implantation process and the annealing process. Subsequently, wiring and similar components are further formed.

Then finally, as illustrated in FIG. 2H, the substrate 1 is thinned using a Back side illumination (BSI) forming process. Here, the structure illustrated in FIG. 2G is inverted upside down, then the substrate 1 is polished from the side of the second surface 1B by a polishing apparatus such as a grinder, and the substrate 1 is thinned to a predetermined thickness. Then, the side of the second surface 1B of the substrate 1 is further polished to expose the first trench T₁ by, for example, a Chemical Mechanical Polishing (CMP) technique.

In this way, the impurity concentration of the P-type region 2 of the photodiode PD can be set to a desired value without worrying about the junction leakage current from the transfer transistor T_{TR} and the reset transistor T_{RS} formed on the surface portion of trench, and the fabrication of the image sensor is extremely easy. Further, a counter-implantation process, in which impurities of opposite conductivity type is implanted for inhibiting a junction leakage current, is not required. This can reduce inequality of impurity concentrations. In addition, in this embodiment, when the first trench T₁ is formed, the trench T_{1A} at the side of the first surface 1A is covered with the sidewall insulation film 12, and then the trench T_{1B} at the side of the second surface 1B is formed with having a diameter (width) approximately the same as that of the trench T_{1A} at the side of the first surface 1A by anisotropic etching. Subsequently, the impurities are implanted into the sidewall of the trench T_{1B} at the side of the second surface 1B. Accordingly, depth of the trench T_{1B} at the side of the second surface 1B can be controlled accurately. And then vertical length of the P-type region 2 of the photodiode PD can be controlled accurately. This ensures controlling the area of junction constituting the photodiode PD as designed so as to ensure formation of a device which precisely represents device characteristics as designed. Further, the junction is formed in the vertical direction along the first trench T₁ passing through the substrate in the thickness direction, and circuit portions such as the transfer transistor T_{TR} and the reset transistor T_{RS} are formed at the surface that is opposite side of the photo-receiving surface, which allows to scale down the occupation area. In addition, this eliminates the need for a complicated mask alignment, thus ensuring a facilitated fabrication.

### Second Embodiment

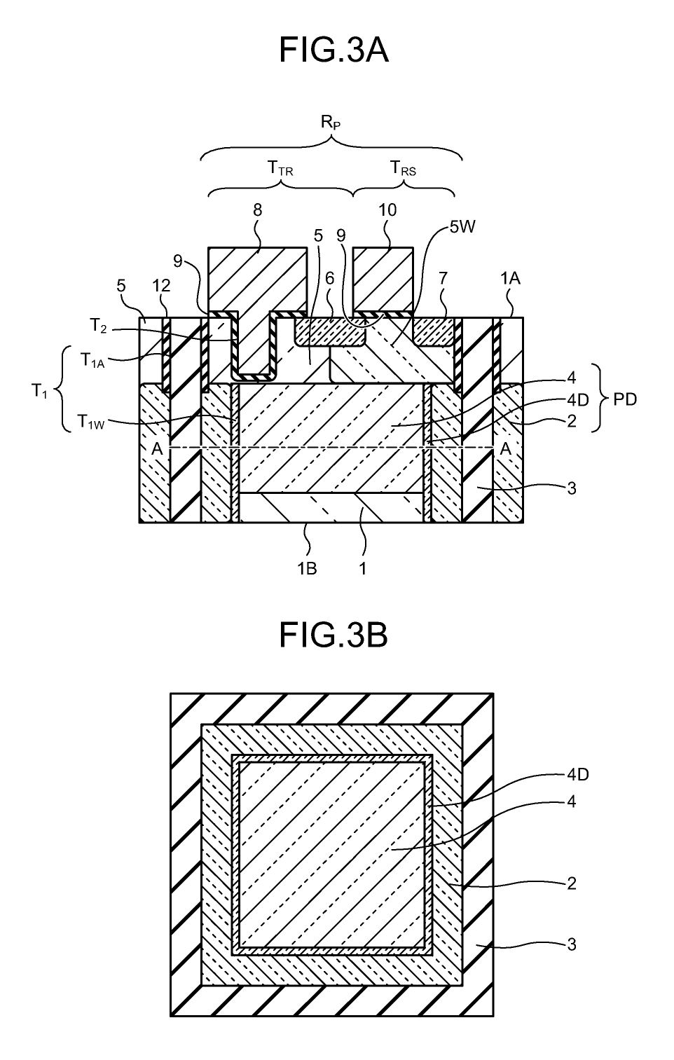

FIGS. 3A and 3B are cross-sectional views schematically illustrating a configuration of an image sensor according to a second embodiment. FIG. 3B is a view illustrating a cross section taken along the line A-A in FIG. 3A. The image sensor of the second embodiment is different from the image sensor of the first embodiment at the point where the image sensor of the second embodiment includes an intermediate concentration N-type region 4D whose impurity concentration is around one digit higher than N-type region 4. The intermediate concentration N-type region 4D is formed in a portion, which contacts the P-type region 2, of the N-type region 4 in the photodiode PD. The intermediate concentration N-type region 4D is formed along the P-type region 2 that is formed along a sidewall of a wide trench T_{1W} of the first trench T₁ at the side of the second surface 1B (photo-receiving surface side), and is formed at a depth approximately the same as the P-type region 2.

Increasing a concentration of the junction and increasing the capacity of the junction are effective for increasing the capacity of the photodiode PD as well as the saturation number of electrons. However, increasing the impurity concentration of the whole N-type region 4 prevents the N-type region 4 from completely being depleted, and then the potential increases disadvantageously. Therefore, this configuration increases an impurity concentration of the N-type region 4 only in a portion forming a junction with the P-type region 2, and does not increase an impurity concentration of the center portion of the N-type region 4 so as to increase the capacity of the photodiode PD and the saturation number of electrons without increasing the electric potential. The other parts of the image sensor of the second embodiment are similar to those of the image sensor of the first embodiment, therefore the detailed description thereof is omitted here, and the same reference numeral will be given to the same element.

Here, similarly to the first embodiment, the N-type region 4 that constitutes the photodiode PD is an impurity diffused region having an impurity concentration around 10¹⁶ cm⁻³ through 10¹⁷ cm⁻³, which is formed by an ion implantation technique, and the intermediate concentration N-type region 4D made of an epitaxial growth layer having an impurity concentration around from 10¹⁷ cm⁻³ through 10¹⁸ cm³ is formed between the N-type region 4 and the P-type region 2. Then the other regions of the image sensor of the second embodiment are similar to those of the image sensor of the first embodiment. That is, the P-type region 2 is an impurity diffused region having an impurity concentration around 10¹⁸ cm⁻³. In addition, a P-type single-crystal silicon substrate having an impurity concentration around 10¹⁶ cm⁻³ is used as the substrate 1. In addition, the low concentration N-type region 5, which becomes a channel of the transfer transistor T_{TR} has an impurity concentration around 10¹⁶ cm⁻³. This low concentration N-type region 5 may be a low concentration P-type region. Also, the P-type well 5W, which becomes a channel of the reset transistor T_{RS}, has an impurity concentration around 10¹⁷ cm⁻³.

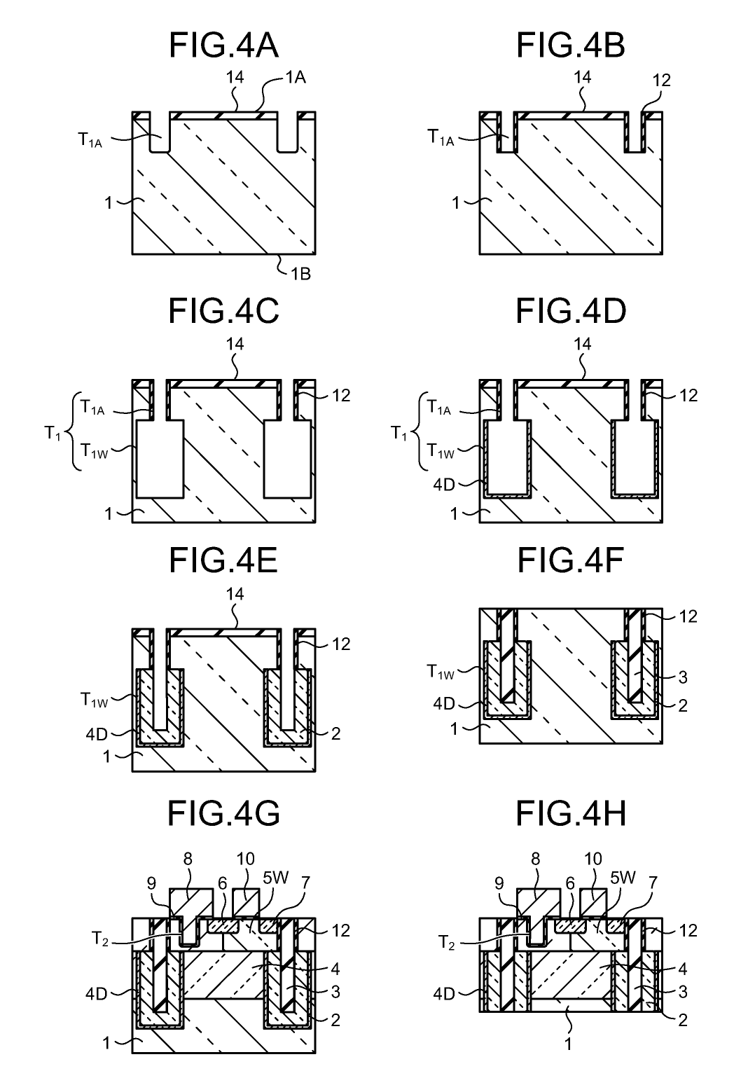

FIGS. 4A through 4H illustrate exemplary fabrication processes of the image sensor according to the second embodiment. First, as illustrated in FIG. 4A, the trench T_{1A} is formed in the first trench T₁ at the 1A side of the first surface 1A by etching part of the first trench T₁ on the substrate 1 by using the hard mask 14.

Then, as illustrated in FIG. 4B, the sidewall insulation film 12 is formed by forming a silicon nitride film by the CVD technique and by etching the silicon nitride film by anisotropic etching so as to leave the silicon nitride film on the sidewall. The processes are same as those of the first embodiment until this point.

Then, as illustrated in FIG. 4C, a wide trench T_{1W} is formed at the side of the second surface 1B by etching the substrate 1 to a desired depth such that wide trench T_{1W} is coupled to the trench T_{1A} at the side of the first surface 1A. Here, the wide trench T_{1W}, which has a larger diameter (width), at the side of the second surface 1B is formed by further etching the substrate 1 from the trench T_{1A} at the side of the first surface 1A. In this process, the wide trench T_{1W} at the side of the second surface 1B is formed by further isotropically etching the substrate 1 from the trench T_{1A} at the side of the first surface 1A, which is covered with the sidewall insulation film 12, toward the second surface 1B while the hard mask 14 is left as it is. This isotropic etching may be dry etching or wet etching.

After that, as illustrated in FIG. 4D, the intermediate concentration N-type region 4D is formed by forming a P-doped silicon layer or an As-doped silicon layer on the wide trench T_{1W} of the first trench T₁ at the side of the second surface 1B by using an epitaxial growth technique. An impurity concentration of the intermediate concentration N-type region 4D is set to, for example, in the order of 10¹⁷ cm⁻³. At this time, the trench T_{1A} of the first trench T₁ at the side of the first surface 1A is covered with the sidewall insulation film 12, and accordingly a film formation is not occurred on the trench T_{1A}. The intermediate concentration N-type region 4D may be formed using the solid phase diffusion technique. In the case where the solid phase diffusion technique is used, impurities are not implanted into the trench T_{1A} at the side of the first surface 1A, which is covered with the sidewall insulation film 12.

Then, as illustrated in FIG. 4E, the P-type region 2 is formed by forming a B-doped silicon layer by using the epitaxial growth technique. Also in the case of the P-type region 2, the P-type region 2 may be formed by forming a silicon layer by using the epitaxial growth technique, and then P-type impurities are implanted into the silicon layer using the ion implantation technique, the solid phase diffusion technique, the plasma doping technique, or similar technique. At this time, the upper side of the trench T_{1A} of the first trench T₁ at the side of the first surface 1A is provided with the sidewall. Accordingly, no film is formed, and impurities are not introduced to the trench T_{1A} at the side of the first surface 1A. Using the plasma doping technique allows forming a shallower impurity diffused region at low temperatures, and then a shallow P-type region 2 having a high concentration can be formed. This allows reducing the occupation area in the horizontal direction.

After this, as illustrated in FIG. 4F, a SiO₂ as the isolating insulation film 3 is filled into the first trench T₁ and the hard mask 14 is peeled off.

Then, the N-type region 4 is formed at a desired depth by implanting N-type impurities by the ion implantation technique.

After that, as illustrated in FIG. 4G, the P-type well 5W is formed by implanting P-type impurities into the surface of the first surface 1A. Also, the transfer transistor T_{TR} is formed by forming the second trench T₂ and by forming the pattern for the transfer gate 8, while the reset transistor T_{RS} is formed by forming the pattern for the reset gate 10. Subsequently, the wirings and similar components are further formed.

Then finally, as illustrated in FIG. 4H, similarly to the first embodiment, the substrate 1 is polished from the side of the second surface 1B, and the substrate 1 is thinned to a predetermined thickness. Then, the side of the second surface 1B of the substrate 1 is further polished to expose the first trench T₁ by the CMP technique.

In addition to the configuration of the image sensor according to the first embodiment, according to the above-described configuration, instead of increasing the impurity concentration of the whole N-type region 4, the impurity concentration of the N type impurities is increased by inserting the intermediate concentration N-type region 4D only at the junction portion between the N-type region 4 and the P-type region 2. Accordingly, the capacity of the photodiode PD and the saturation number of electrons can be increased while preventing the electric potential increase. In the fabrication, the image sensor of the second embodiment can be fabricated easily by merely replacing the etching process for forming the trench at the side of the second surface 1B of the substrate 1 by an isotropic etching to form the wide trench T_{1W} at the second surface 1B as, and by adding the epitaxial growth technique or the diffusion process.

Thus in this embodiment, although the junction portion is highly concentrated by inserting the intermediate concentration N-type region 4D only at the junction portion between the N-type region 4 and the P-type region 2, more than one layers whose impurity concentrations are different from one another may be formed, or a composition inclined layer whose impurity concentration gradually changes may be formed. It should be noted that the N-type region 4 formed at the center side of the pixel region R_{P} which contacts with the P-type region 2 constituting the photodiode PD has a high impurity concentration at a portion near boundary with the P-type region 2, while having a low impurity concentration at the center portion.

### Third Embodiment

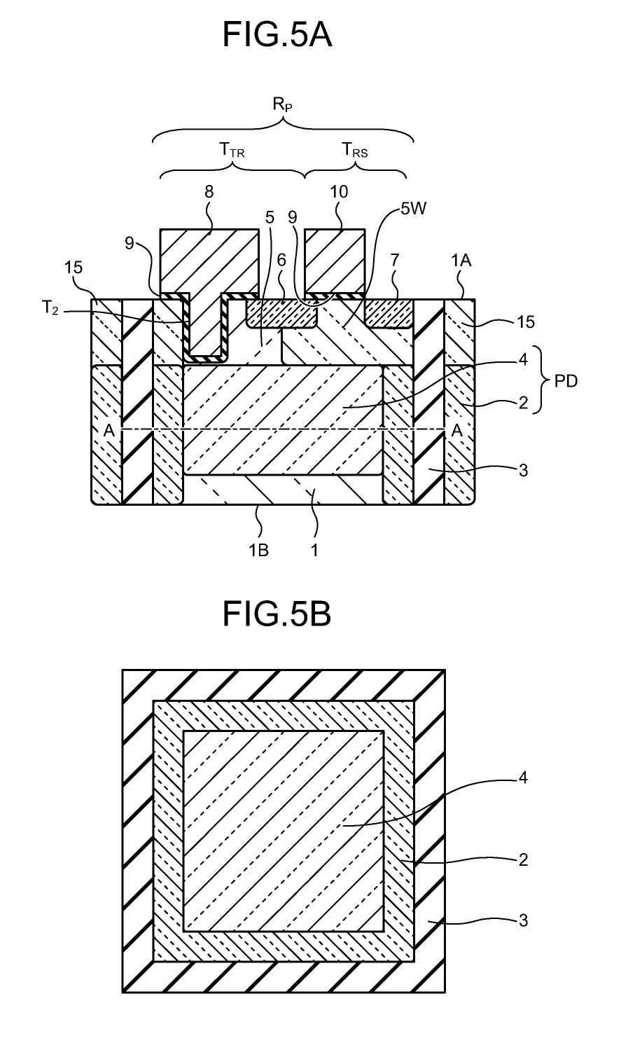

FIGS. 5A and 5B are cross-sectional views schematically illustrating a configuration of an image sensor according to a third embodiment. FIG. 5B is a view illustrating a cross section taken along the line A-A in FIG. 5A. The image sensor of the third embodiment is different from the image sensor of the first embodiment at the point where the image sensor of the third embodiment does not include the sidewall insulation film 12 in the first trench T₁ at the side of the first surface 1A. Instead of that, the image sensor of the third embodiment includes, at the side of the first surface 1A, an intermediate concentration P-type region 15 whose impurity concentration is lower, by around one digit lower than the P-type region 2 that contacts the N-type region 4 of the photodiode PD. The intermediate concentration P-type region 15 is formed by counter-implanting ions of opposite conductivity type. Here, an impurity concentration of the P-type region 2 is set to around 10¹⁸ cm⁻³, while an intermediate concentration P-type region 15 is set to around 10¹⁷ cm⁻³.

Also in this embodiment, the photodiode PD is embedded in the pixel region R_{P}, and has the P-type region 2 formed along the first trench T₁, and the N-type region 4 formed inside the P-type region 2. The hole concentration of the P-type region 2 is decreased by cancelling by means of a counter-implantation of N-type impurities of opposite conductivity type at the side of the first surface 1A by implanting ions from the oblique direction. As a result, actual impurity concentration is different between the side of the second surface 1B and the side of the first surface 1A, and an impurity concentration of the P-type region 2 at the side of the second surface 1B is higher than an impurity concentration of the intermediate concentration P-type region 15 at the side of the first surface 1A. The PN-junction of the photodiode PD is formed at the side of the second surface 1B with being approximately parallel to the direction of the first trench T₁. Then, the transferring portion includes the transfer transistor T_{TR} that is made of a trench type MISFET including the transfer gate 8, which is formed in the second trench T₂ formed from the first surface 1A of the substrate 1 toward the second surface 1B on which the photodiode PD is formed. The transferring portion transfers an electric charge to the floating diffusion portion 6.

After forming a P-type impurity diffused region of high impurity concentration on the sidewall of the first trench T₁, some of impurities in the P-type impurity diffused region on the sidewall of the trench T_{1A} at the side of the first surface 1A are canceled by a counter-implantation. It decreases the effective P-type impurity concentration to form the intermediate concentration P-type region 15. This allows decreasing an impurity concentration in the channel region of the transfer transistor T_{TR} and then reducing a junction leakage current from the transfer transistor T_{TR} and the reset transistor T_{RS}. In addition, an impurity concentration of the intermediate concentration P-type region 15 can be freely decreased by a counter-implantation, which allows setting an impurity concentration of the P-type region 2 to an impurity concentration appropriate for the photodiode PD.

The other parts are similar to those of the first embodiment, and therefore the detailed description is omitted.

According to the image sensor of this embodiment, a junction leakage current from the transfer transistor T_{TR} and the reset transistor T_{RS} can be inhibited since, at the upper portion of the first trench T₁ that constitutes the FDTI, that is, at the side of the first surface 1A, the P-type region 2 of high impurity concentration is not formed, instead of that, the intermediate concentration P-type region 15 is formed. Also, an impurity concentration of the P-type region 2 of the photodiode PD can be increased to increase the capacity of the photodiode PD since there is no need to constrain impurity concentration to the level to suppress junction leakage current along the entire length of the trench.

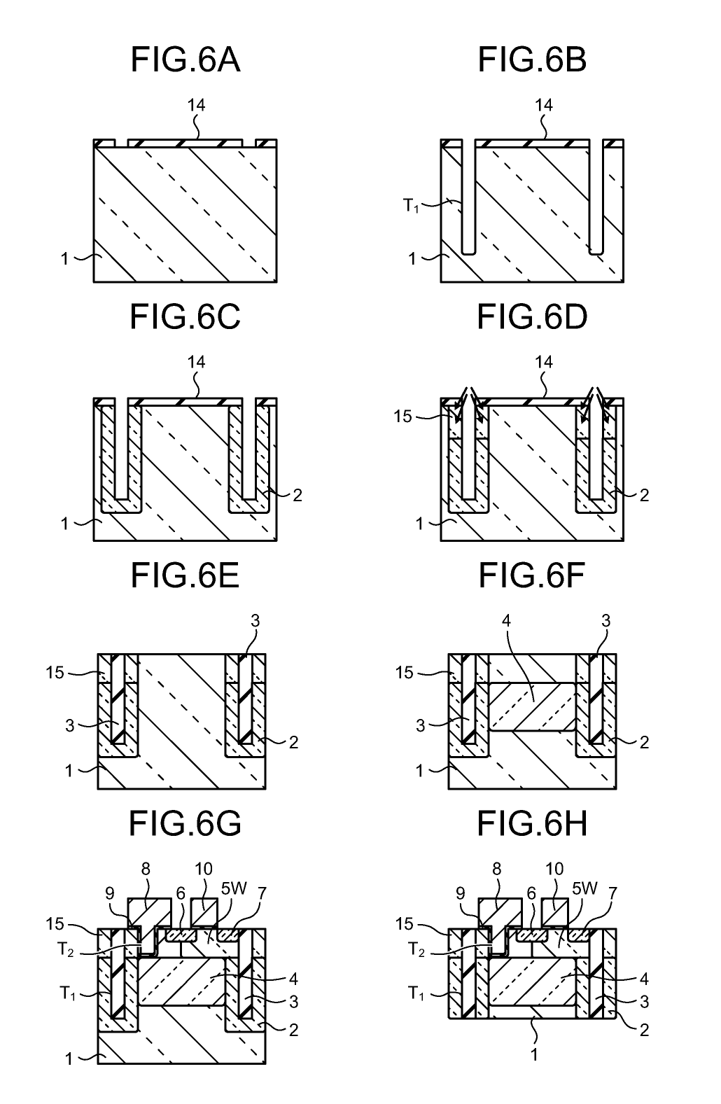

FIGS. 6A through 6H illustrate exemplary fabrication processes of the image sensor according to the third embodiment. First, as illustrated in FIG. 6A, the hard mask 14 is formed.

Then, as illustrated in FIG. 6B, the first trench T₁ is formed by etching the substrate 1 by using the hard mask 14 until a depth where the first trench T₁ later passes through the substrate 1 after the substrate 1 is thinned using the BSI process. Here, the first trench T₁ for isolating and defining the pixel region R_{P} is formed in one process from the side of the first surface 1A toward the side of the second surface 1B.

Then, as illustrated in FIG. 6C, the P-type region 2 is formed by using the ion implantation technique by introducing P-type impurities from the side surface.

After that, as illustrated in FIG. 6D, the intermediate concentration P-type region 15 is formed by implanting N-type impurities to the inner wall of the first trench T₁ by using an oblique ion implantation whose inclined angle is larger than that of the forming process of the P-type region 2. This implanting cancels the P-type impurities at a first (predetermined) portion of the upper side of the side wall of the side of the first surface 1A. At this time, the P-type region 2 of high impurity concentration is maintained at the side of the second surface 1B.

Then, as illustrated in FIG. 6E, a SiO₂ as the isolating insulation film 3 is filled into the first trench T₁ and the hard mask 14 is peeled off.

Then, as illustrated in FIG. 6F, the N-type region 4 is formed at a desired depth by the ion implantation technique.

After that, as illustrated in FIG. 6G, the P-type well 5W is formed at the side of the first surface 1A. Also, the transfer transistor T_{TR} is formed by forming the second trench T₂ and by forming the pattern for the transfer gate 8, while the reset gate 10 is formed by forming the pattern for the reset transistor T_{RS}. After that, the wirings or similar component are further formed.

Then finally, as illustrated in FIG. 6H, similarly to the first and second embodiments, a substrate 1P is thinned using the BSI process.

In this way, an impurity concentration of the P-type region 2 of the photodiode PD can be set to a desired value without worrying about the junction leakage current from the transfer transistor T_{TR} and the reset transistor T_{RS} formed on the surface layer portion of the trench, and the fabrication of the image sensor is extremely easy. Simply adding a counter-implantation process, in which impurities of opposite conductivity type are implanted for inhibiting a junction leakage current, ensures a facilitated fabrication without requiring the formation of the sidewall insulation film.

Note that, in the first embodiment through the third embodiment, although the PN-junction is formed along the peripheral surface of the first trench T₁ across the whole circumference in the element region defined by the element isolation region formed by the first trench T₁, the PN-junction is not necessarily formed along the whole circumference, and the PN-junction may be, for example, formed at two sides or three sides of the first trench T₁.

Hereinabove, the exemplary embodiments are described with reference to specific examples. However, the embodiments are not limited to these specific examples. That is, also examples in which a person skilled in the art have appropriately added a design modification to the specific examples, are included within the scope of the embodiments as long as they are provided with the characteristics of the embodiments. Each of a component and an arrangement thereof, a material, conditions, a shape, a size or a similar element included by each of the specific examples described above are not limited to the exemplary examples, and can be appropriately modified.

Also, each component included in each of the above described embodiments can be combined as long as they are technically possible, and examples made by combining them are also included within the scope of the embodiments as long as they include the characteristics of the embodiments. In addition, it should be understood that, in the concept category of the embodiments, a person skilled in the art can conceive various kinds of variations, and these variations are also included within the scope of the embodiments.

For example, although some components are removed from all the components described in the above-described first embodiment through the third embodiment or in each of the embodiments, if the problems described in the section of technical problem are solved, the configuration in which these components are removed may be extracted as the invention. Further, the components of the above-described first embodiment through third embodiment may be appropriately combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a pixel region formed on a semiconductor substrate, the pixel region being separated by a first trench passing from a first surface to a second surface,
a photodiode embedded in the pixel region, the photodiode having a P-type region formed along the first trench at a side of the second surface, and
a MISFET formed on the first surface of the semiconductor substrate, the MISFET having a transfer gate transferring an electric charge from the photodiode,
wherein an impurity concentration of P-type impurities along the first trench is different between at a side of the first surface and at the side of the second surface, and
an impurity concentration of the P-type region formed at the side of the second surface and constituting the photodiode is higher than an impurity concentration at the side of the first surface.

2. The semiconductor device according to claim 1,
wherein an impurity concentration of an N-type region formed at a center side of the pixel region in contact with the P-type region constituting the photodiode is high at a portion near boundary with the P-type region and low at the center portion.

3. The semiconductor device according to claim 1,
wherein the transfer gate is formed in a second trench formed from the first surface of the semiconductor substrate toward the second surface.

4. The semiconductor device according to claim 1,
wherein the first trench has an inner wall covered with a sidewall insulation film until a first depth at the side of the first surface, and
the P-type region formed along the first trench at the side of the second surface constitutes the photodiode, the first trench being revealed from the sidewall insulation film at the side of the second surface.

5. The semiconductor device according to claim 4,
wherein the P-type region is selectively formed along the first trench at the side of the second surface, and the P-type region is not formed at the side of the first surface.

6. The semiconductor device according to claim 5,
wherein the P-type region is not formed along a portion of the first trench where the inner wall of the first trench is covered with the sidewall insulation film.

7. The semiconductor device according to claim 1,
wherein the P-type region has a P-type impurity concentration that is lower at the side of the first surface than at the side of the second surface by a counter-implantation of impurities of opposite conductivity type into the inner wall of the first trench at the side of the first surface.

8. The semiconductor device according to claim 1,
wherein the P-type region constituting the photodiode faces a lower concentration N-type region via a high concentration N-type region.

9. The semiconductor device according to claim 8,
wherein the high concentration N-type region is an epitaxial growth layer formed on the inner wall of the first trench, and
the P-type region is an epitaxial growth layer formed along an inner wall of the high concentration N-type region.

10. The semiconductor device according to claim 8,
wherein the high concentration N-type region is an N-type impurity diffused layer formed on the inner wall of the first trench, and
the P-type region is a P-type impurity diffused layer formed along an inner wall of the high concentration N-type region.

11. The semiconductor device according to claim 8,
wherein the first trench is formed to have width larger at the side of the second surface than at the side of the first surface.

12. The semiconductor device according to claim 4,
wherein the first trench is filled with a silicon oxide film, and
the sidewall insulation film is a silicon nitride film.

13. A semiconductor device comprising:
a pixel region formed on a semiconductor substrate, the pixel region being separated by a first trench passing from a first surface to a second surface,
a photodiode embedded in the pixel region, the photodiode having a P-type region formed along the first trench, and
a MISFET formed on the first surface of the semiconductor substrate, the MISFET having a transfer gate transferring an electric charge from the photodiode,
wherein the first trench has an inner wall covered with a sidewall insulation film until a first depth at a side of the first surface, and
the P-type region formed along the first trench at a side of the second surface constitutes the photodiode, the first trench being revealed from the sidewall insulation film at the side of the second surface.

14. A method for fabricating a semiconductor device comprising:
forming a first trench that surrounds to define a pixel region from a side of a first surface of a semiconductor substrate toward a side of a second surface opposing to the first surface,
forming a P-type region such that an impurity concentration along the first trench is different between at the side of the first surface and at the side of the second surface, and the impurity concentration is higher at the side of the second surface than at the side of the first surface,
filling an insulation film into the first trench,
forming, at the side of the second surface in the pixel region, a first N-type region constituting a photodiode with the P-type region, and
forming, on the first surface of the semiconductor substrate, a MISFET including a transfer gate transferring an electric charge from the photodiode.

15. The method for fabricating a semiconductor device according to claim 14,
wherein the forming the first trench includes:
forming a trench at the side of the first surface having a first depth from the side of the first surface,
covering the trench at the side of the first surface with a sidewall insulation film, and
forming a trench at the side of the second surface from the trench at the side of the first surface covered with the sidewall insulation film further toward the second surface, and
wherein the forming the P-type region includes forming a P-type region along the trench at the side of the second surface revealed from the sidewall insulation film.

16. The method for fabricating a semiconductor device according to claim 15,
wherein the forming the trench at the side of the second surface includes forming, by anisotropic etching, a trench having an approximately same width as a width of the trench at the side of the first surface.

17. The method for fabricating a semiconductor device according to claim 16,
wherein the forming the P-type region includes introducing P-type impurities from a side face of the trench at the side of the second surface revealed from the sidewall insulation film.

18. The method for fabricating a semiconductor device according to claim 15,
wherein the forming the trench at the side of the second surface includes forming a wide width trench at the side of the second surface having a larger width than the trench at the side of the first surface by isotropic etching, and
wherein the method further includes forming, prior to forming the P-type region, a second N-type region with an impurity concentration larger than an impurity concentration of the first N-type region along the wide width trench at the side of the second surface.

19. The method for fabricating a semiconductor device according to claim 18,
wherein the forming the second N-type region and the forming the P-type region each include forming an epitaxial growth layer along the wide width trench at the side of the second surface.

20. The method for fabricating a semiconductor device according to claim 14,
wherein the forming the P-type region includes:
introducing P-type impurities along the first trench,
implanting, by an oblique ion implantation technique, N-type impurities to an inner wall of the first trench to which the P-type impurities have been introduced to cancel the P-type impurities at a first depth region from the first surface so as to decrease a concentration of the P-type impurities.
